(19) United States
(12) Patent Application Publication
(10) Pub. No.: US 2026/0142670 A1
(43) Pub. Date: May 21, 2026

(54) SWITCH-CAPACITOR FILTER FOR RECEIVER BASEBAND ANTI-ALIASING SIGNAL FILTERING

(71) Applicant: QUALCOMM Incorporated, San Diego, CA (US)

(72) Inventor: Hongying WANG, Cambridge (GB)

(21) Appl. No.: 18/949,633

(22) Filed: Nov. 15, 2024

(51) Int. Cl. H03M 1/12; H03M 1/38

(52) U.S. Cl. CPC H03M 1/1245; H03M 1/38

(57) ABSTRACT

An apparatus, including: a switched capacitor filter; and an analog-to-digital converter (ADC) including an input coupled to the switched capacitor filter. A method, includes: operating a switched capacitor filter to filter an input analog signal to generate an output analog signal; and converting the output analog signal into a digital signal.

### FIELD

This disclosure relates generally to filters, and in particular, to a switched-capacitor filter for receiver baseband anti-aliasing signal filtering.

### BACKGROUND

A receiver may include an antenna to wirelessly sense a radio frequency (RF) signal, a low noise amplifier (LNA) to amplify the RF signal, a mixer and local oscillator (LO) to collectively frequency downconvert the RF signal into an unfiltered baseband signal, a baseband filter to filter the unfiltered baseband signal to generate a baseband analog signal, and an analog-to-digital converter (ADC) to convert the baseband analog signal into a digital baseband signal. It may be desirable for the baseband filter to perform anti-aliasing filtering, while consuming relatively small amount of power/current, occupying relatively small circuit or integrated circuit (IC) footprint, and performing the filtering in a substantially linear manner.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes a switched capacitor filter, and an analog-to-digital converter (ADC) including an input coupled to the switched capacitor filter.

Another aspect of the disclosure relates to a method. The method includes: operating a switched capacitor filter to filter an input analog signal to generate an output analog signal; and converting the output analog signal into a digital signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example receiver in accordance with an aspect of the disclosure.

FIG. 2 illustrates a block diagram of an example baseband signal processing circuit in accordance with another aspect of the disclosure.

FIG. 3 illustrates a block diagram of another example baseband signal processing circuit in accordance with another aspect of the disclosure.

FIG. 4 illustrates a block diagram of another example baseband signal processing circuit in accordance with another aspect of the disclosure.

FIG. 5 illustrates a block diagram of another example baseband signal processing circuit in accordance with another aspect of the disclosure.

FIG. 6A illustrates a schematic diagram of another example switched capacitor finite impulse response (FIR) filter in accordance with another aspect of the disclosure.

FIG. 6B illustrates a timing diagram of an example operation of the switched capacitor finite impulse response (FIR) filter of FIG. 6A in accordance with another aspect of the disclosure.

FIG. 7A illustrates a schematic diagram of another example switched capacitor infinite impulse response (IIR) filter in accordance with another aspect of the disclosure.

FIG. 7B illustrates a timing diagram of an example operation of the switched capacitor infinite impulse response (IIR) filter of FIG. 7A in accordance with another aspect of the disclosure.

FIG. 8 illustrates a graph of an example frequency response of the switched capacitor finite impulse response (FIR) filter of FIG. 6A in accordance with another aspect of the disclosure.

FIG. 9 illustrates a graph of an example frequency response of the switched capacitor infinite impulse response (IIR) filter of FIG. 7A in accordance with another aspect of the disclosure.

FIG. 10 illustrates a block diagram of another example baseband signal processing circuit in accordance with another aspect of the disclosure.

FIG. 11 illustrates a block diagram of another example apparatus (e.g., receiver) in accordance with another aspect of the disclosure.

FIG. 12 illustrates a flow diagram of an example method of filtering a baseband signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

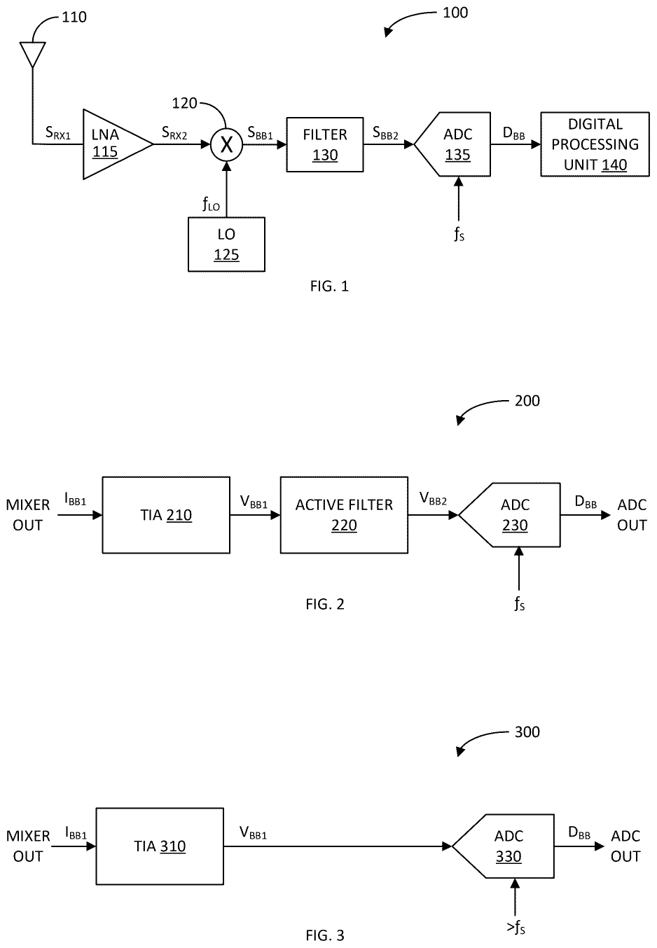

FIG. 1 illustrates a block diagram of an example receiver (Rx) 100 in accordance with an aspect of the disclosure. The receiver 100 may be implemented to receive and process wireless wide area network (WWAN) signals (e.g., Fifth or Sixth Generation (5G or 6G) New Radio (NR) signals), wireless local area network (WLAN) signals (e.g., WiFi signals), personal area network (PAN) signals (e.g., Bluetooth signals), etc.

The receiver 100 includes an antenna 110, a low noise amplifier (LNA) 115, a mixer 120, a local oscillator (LO) 125, a filter 130, an analog digital converter (ADC) 135, and a digital processing unit (DPU) 140. The antenna 110 is configured to sense a wireless radio frequency (RF) signal S_{RX1}. The LNA 115 is configured to amplify the received RF signal S_{RX1} to generate an amplified RF signal S_{RX2}. The mixer 120 is configured to mix the amplified RF signal S_{RX2} with a local oscillator (LC) clock signal f_{LO} generated by the LO 125 to generate an unfiltered baseband signal S_{BB1}.

The receiver 100 further includes a filter 130 configured to filter the unfiltered baseband signal S_{BB1} to remove higher frequency mixing components from the unfiltered baseband signal S_{BB1} and for anti-aliasing in connection with the following analog-to-digital conversion. Accordingly, the filter 130 is configured to generate a filtered baseband signal S_{BB2}. The ADC 135 is configured to convert the filtered baseband signal S_{BB2} into a digital baseband signal D_{BB} based on a sampling clock signal f_{S}. The DPU 140 is configured to process the digital baseband signal D_{BB} to extract information/data therein.

As discussed further herein, using WLAN application as an example, the WLAN Rx baseband processing should have relatively high gain and high bandwidth requirements for different channel modes (e.g., 20 mega Hertz (MHz) or 40 MHz bandwidth channel modes). For example, the high gain baseband requirement may be needed for bandwidth, error vector measurement (EVM), and signal-to-noise ratio (SNR) requirements. The WLAN Rx baseband filter requirements may be further needed to attenuate out-of-band blockers, as well as for reducing aliasing in the following analog-to-digital conversion of the received baseband signal. Additionally, such high gain and bandwidth requirements should be achieved in a low power/current consumption manner, in a substantially linear manner, while occupying a relatively small circuit or integrated circuit (IC) footprint manner.

FIG. 2 illustrates a block diagram of an example baseband signal processing circuit 200 in accordance with another aspect of the disclosure. With reference to the receiver 100, the baseband signal processing circuit 200 may be situated between the mixer 120 and the DPU 140. The baseband signal processing circuit 200 includes a transimpedance amplifier (TIA) 210, an active filter 220, and an analog-to-digital converter (ADC) 230.

The unfiltered baseband signal S_{BB1} generated by the mixer 120 may be a current signal, such as I_{BB1}. Accordingly, the TIA 210 is configured to filter the unfiltered baseband current signal I_{BB1} to substantially remove higher frequency mixing components from the current signal I_{BB1} to generate a first filtered voltage signal V_{BB1}. The active filter 220 is configured to filter the first filtered voltage signal V_{BB1} for anti-aliasing purpose (e.g., to substantially remove/reject signal components of the first filtered voltage signal V_{BB1} above the sampling clock signal f_{S} of the ADC 230) to generate a second filtered voltage signal V_{BB2}. The ADC 230 is configured to convert the second filtered voltage signal V_{BB2} into a digital baseband signal D_{BB} based on the sampling clock signal f_{S}.

One advantage of the baseband signal processing circuit 200 is that the active filter 220 relaxes the frequency of the sampling clock signal f_{S} applied to the ADC 230 for anti-aliasing purposes. However, a drawback of the baseband signal processing circuit 200 is that the active filter 220 may require an operational amplifier (Op Amp), which consumes significant power/current and occupies significant circuit or IC footprint.

FIG. 3 illustrates a block diagram of another example baseband signal processing circuit 300 in accordance with another aspect of the disclosure. Similarly, with reference to the receiver 100, the baseband signal processing circuit 300 may be situated between the mixer 120 and the DPU 140. The baseband signal processing circuit 300 includes a transimpedance amplifier (TIA) 310 and an analog-to-digital converter (ADC) 330. Accordingly, the baseband signal processing circuit 300 is similar to baseband signal processing circuit 200 without the active filter 200.

As discussed, the unfiltered baseband signal S_{BB1} generated by the mixer 120 may be a current signal, such as I_{BB1}. Accordingly, the TIA 310 is configured to filter the unfiltered baseband current signal I_{BB1} to substantially remove higher frequency mixing components from the current signal I_{BB1} to generate a filtered voltage signal V_{BB}. The TIA 310 may also be configured to filter the unfiltered baseband current signal I_{BB1} for anti-aliasing purpose as the frequency of the sampling clock signal f_{S} may be set to oversample the filtered voltage signal V_{BB}; thereby, relaxing the filter requirement of the unfiltered baseband current signal I_{BB1}. And, as mentioned, the ADC 330 is configured to convert the filtered voltage signal V_{BB} into a digital baseband signal D_{BB} based on an oversampling sampling clock signal>f_{S}.

As discussed, one advantage of the baseband signal processing circuit 300 include relaxing the baseband anti-aliasing filtering requirement due to the oversampling sampling clock signal>f_{S} of the ADC 330. Another advantage of the baseband signal processing circuit 300 is that an active filter may not be required; resulting in less power/current consumption and smaller circuit IC footprint. However, the oversampling clock signal>f_{S} typically degrades the settling performance of the ADC 330; increases the power/current consumption of the ADC 330; may require time-interleaving ADCs to handle the higher frequency of the oversampling clock signal>f_{S}; and may require reducing the decimation ratio of the digital baseband signal D_{BB}, which further increases power/current and IC footprint consumption.

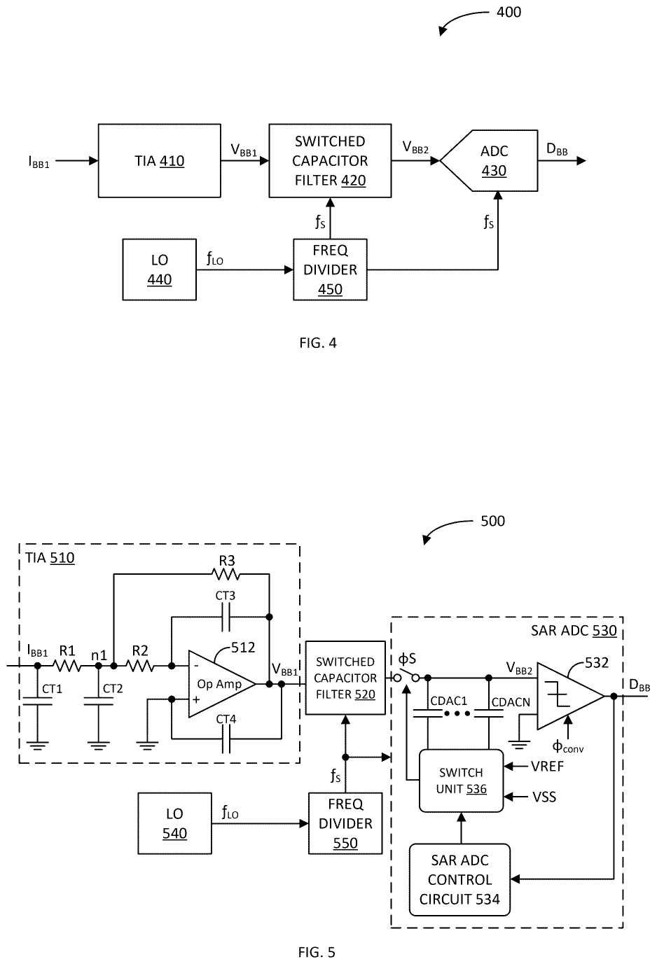

FIG. 4 illustrates a block diagram of another example baseband signal processing circuit 400 in accordance with another aspect of the disclosure. In summary, the baseband signal processing circuit 400 includes a switched capacitor filter 420 coupled between a TIA 410 and an ADC 430. As discussed further herein, the switched capacitor filter 420 performs its filtering operation based on capacitor charge sharing. The switched capacitor filter 420 may not require calibration or trimming because the transfer function is based on capacitance ratio. The switched capacitor filter 420 may be scaled for different bandwidth channel modes (e.g., 20 MHz or 40 MHz). The switched capacitor filter 420 may have good linearity characteristics, as it is essentially comprised of pseudo-passive devices, such as capacitors and switching devices (e.g., field effect transistors (FETs) used as switching devices). The switched capacitor filter 420 may be tailored for low power/current consumption and occupying small circuit or IC footprint.

As discussed, the baseband signal processing circuit 400 includes the TIA 410, the switched capacitor filter 420, and the ADC 430. Additionally, the baseband signal processing circuit 400 further includes a local oscillator (LO) 440 and a frequency divider 450. The TIA 410 is configured to filter the unfiltered baseband current signal I_{BB1} to substantially remove higher frequency mixing components from the current signal I_{BB1} to generate a first filtered voltage (analog) signal V_{BB1}. The switched capacitor filter 420 is configured to perform anti-aliasing filtering of the first filtered voltage signal V_{BB1} to generate a second baseband voltage signal V_{BB2} based on the sampling clock signal f_{S}. The ADC 430 is configured to convert the second filtered voltage signal V_{BB2} into a digital baseband signal D_{BB} based on the sampling clock signal f_{S}.

The LO 440 is configured to generate an LO clock signal f_{LO} (which may also be provided to the mixer 120 for frequency down conversion). The frequency divider 450 is configured to frequency divide the LO clock signal f_{LO} (e.g., with a divider ratio of two (2) or other) to generate the sampling clock signal f_{S} for the switched capacitor filter 420 and the ADC 430.

FIG. 5 illustrates a block diagram of another example baseband signal processing circuit 500 in accordance with another aspect of the disclosure. The baseband signal processing circuit 500 may be an example more detailed implementation of the baseband signal processing circuit 400.

In particular, the baseband signal processing circuit 500 includes a TIA 510, a switched capacitor filter 520, an ADC 530, a local oscillator (LO) 540, and a frequency divider 550. The TIA 510 is configured to filter the unfiltered baseband current signal I_{BB1} to substantially remove higher frequency mixing components from the current signal I_{BB1} to generate a first filtered voltage (analog) signal V_{BB1}. The switched capacitor filter 520 is configured to perform anti-aliasing filtering of the first filtered voltage signal V_{BB1} to generate a second baseband voltage signal V_{BB2} based on the sampling clock signal f_{S}. The ADC 530 is configured to convert the second filtered voltage signal V_{BB2} into a digital baseband signal D_{BB} based on the sampling clock signal f_{S}.

The LO 540 is configured to generate an LO clock signal f_{LO} (which may also be provided to the mixer 120 for frequency down conversion). The frequency divider 550 is configured to frequency divide the LO clock signal f_{LO} (e.g., with a divider ratio of two (2) of other) to generate the sampling clock signal f_{S}. The sampling clock signal f_{S} is provided to the switched capacitor filter 520 for anti-aliasing filtering, and to the ADC 530 for analog-to-digital conversion, as discussed further herein.

With regard to details, the TIA 510 includes a first input shunt capacitor CT1 (e.g., coupled between the input of the TIA 510 and a lower voltage rail, such as ground), a first input series resistor R1, a second input shunt capacitor CT2 (e.g., coupled between a node n1 and ground), and a second input series resistor R2. The TIA 510 further includes an operational amplifier 512 including a first (e.g., negative) input, a second (e.g., positive) input, and an output. The first and second input series resistors R1 and R2 are coupled between the input of the TIA 510 and the first (e.g., negative) input of the operational amplifier 512. The output of the operational amplifier 512 is coupled to an input of the switched capacitor filter 520.

The TIA 510 includes a feedback resistor R3 coupled between the output of the operational amplifier 512 and node n1 between the first and second input series resistors R1 and R2. The TIA 510 further includes a first feedback capacitor CT3 coupled between the output and the first (e.g., negative) input of the operational amplifier 512. The TIA 510 further includes a second feedback capacitor CT4 coupled between the output and the second (e.g., positive) input of the operational amplifier 512. The second (e.g., positive) input of the operational amplifier 512 may be coupled to common mode voltage, direct current (DC or 0 Volt (V)) and/or alternating circuit (AC) ground (generally “ground”), and also can be differential design.

The ADC 530 may be implemented as a successive approximation register (SAR) ADC. In this regard, the SAR ADC 530 includes a sampling switching device φS, a set of N binary-weighted capacitors CDAC1 to CDACN (e.g., where N is an integer), a comparator 532, an SAR ADC control circuit 534, and a switch unit 536 (e.g., a monolithic switch unit). The sampling switching device φS is coupled between the output of the switched capacitor filter 520 and a first input of the comparator 532. The set of N binary-weighted capacitors CDAC1 to CDACN include respective first terminals coupled the first input of the comparator 532, where the comparator 532 may include a second input coupled to ground if single-ended. The comparator 532 includes an input configured to receive a conversion clock signal φconv. The comparator 532 includes an output coupled to an input of the SAR ADC control circuit 534. The SAR ADC control circuit 534 includes an output coupled to the switch unit 536. The switch unit 536 is coupled to respective second terminals of the set of N shunt capacitors CDAC1 to CDACN, and the sampling switching device φS. The switch unit 536 further includes inputs configured to receive a reference voltage VREF and ground potential if single-ended, respectively.

The conversion of the second baseband voltage signal V_{BB2} to the digital baseband signal D_{BB} may begin by closing the sampling switching device φS to provide a sample of the second baseband voltage signal V_{BB2} to the first input of the comparator 532. After the second baseband voltage signal V_{BB2} is sampled, the sampling switching device φS is open. Then, through a feedback successive approximation algorithm, the SAR ADC control circuit 534, via the switch unit 536, successively applies either the reference voltage VREP or ground to each of the set of N binary-weighted (e.g., from the most significant bit (MSB) to the least significant bit (LSB)) so as to reduce the second baseband voltage signal V_{BB2} to substantially zero (0) Volt or ground. At such time, the output digital baseband signal D_{BB} is the digital conversion of the second baseband voltage signal V_{BB2}. Each analog-to-digital conversion of the second baseband voltage signal V_{BB2} to the digital baseband signal D_{BB} occurs once a period of the sampling frequency f_{S}.

As discussed further herein, the switched capacitor filter 520 also operates in accordance with the sampling frequency f_{S} to provide the sample of the second baseband voltage signal V_{BB2} to the SAR ADC 530 once a period of the sampling frequency f_{S}. Accordingly, the operation of the switched capacitor filter 520 may be synchronous with the operation of the SAR ADC 530.

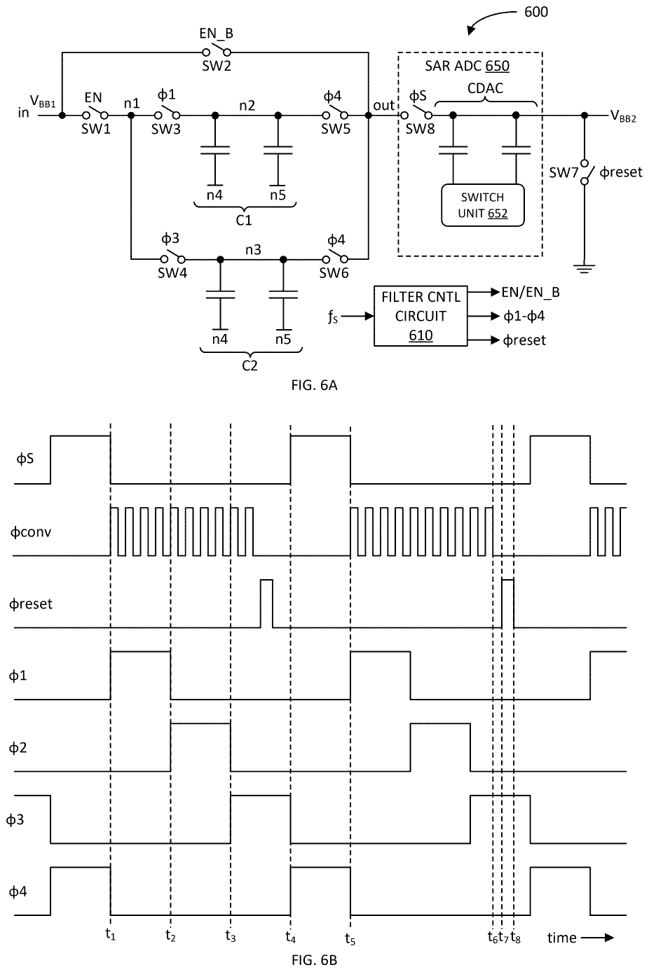

FIG. 6A illustrates a schematic diagram of an example switched capacitor finite impulse response (FIR) filter 600 in accordance with another aspect of the disclosure. The switched capacitor FIR filter 600 may be an example implementation of the switched capacitor filter 420 or 520 of baseband signal processing circuit 400 or 500, respectively.

The switched capacitor FIR filter 600 includes a set of switching devices SW1 to SW7, a first set of one or more capacitors C1, a second set of one or more capacitors C2, and a filter control circuit 610. Each of the set of switching devices SW1 to SW7 may be implemented as a field effect transistor (FET) type device. The switched capacitor FIR filter 600 is coupled to a SAR ADC 650 (e.g., only a relevant portion thereof is shown within a dashed box for description purpose).

The first switching device SW1 is coupled between an input (in) of the switched capacitor FIR filter 600 and a first node n1. The second switching device SW2 is coupled between the input of the switched capacitor FIR filter 600 and a fourth node n4. The first and second switching devices SW1-SW2 are for selectively enabling/disabling the switched capacitor FIR filter 600 based on complementary enable signals EN and EN_B, which control the ON/OFF states of the first and second switching devices SW1 and SW2, respectively (e.g., EN/EN_B=1/0→filter 600 enabled; EN/EN_B=0/1→filter 600 disabled).

The third switching device SW3 is coupled between the first node n1 and a second node n2. The ON/OFF state of the third switching device SW3 is responsive to a first phase φ1 related to a sampling clock signal φS of the SAR ADC 650 (e.g., φ1=1→ON; φ1=0→OFF). The fourth switching device SW4 is coupled between the first node n1 and a third node n3. The ON/OFF state of the fourth switching device SW3 is responsive to a third phase φ3 related to the sampling clock signal φS of the SAR ADC 650 (e.g., φ3=1→ON; φ3=0→OFF).

The first set of one or more capacitors C1 is coupled between the second node n2 and a set of one or more nodes n4−n5. The second set of one or more capacitors C2 is coupled between the third node n3 and the set of one or more nodes n4−n5. In the case where the switched capacitor FIR filter 600 is configured to filter a single-ended baseband signal V_{BB1}, the set of one or more nodes is coupled to a lower voltage rail (e.g., n4=n5=ground). In the case wherein the switched capacitor FIR filter 600 is configured to filter a differential signal, where the signal V_{BB1} represents one side of the differential signal, the set of one or more nodes n4−n5 may be coupled to source of a common mode voltage (e.g., n4=n5=vcm), or a source of a positive reference voltage VREFP and a source of a negative reference voltage VREFN (e.g., n4=VREFP, n5=VREFN). If the common mode voltage vcm is not available, an equivalent common mode voltage may be generated by applying the positive reference voltage VREFP to half (e.g., one of two of them) of each of the sets of capacitors C1 and C2, and applying the negative reference voltage VREFN to the other half (e.g., the other of two of them) of each of the sets of capacitors C1 and C2.

The fifth switching device SW5 is coupled between the second node n2 and an output (out) of the switched capacitor filter 600. The ON/OFF state of the fifth switching device SW5 is responsive to a fourth phase φ4 related to the sampling clock signal φS of the SAR ADC 650 (e.g., φ4=1→ON; φ4-0→OFF). The sixth switching device SW6 is coupled between the third node n3 and the output of the switched capacitor filter 600. The ON/OFF state of the sixth switching device SW6 is also responsive to the fourth phase φ4. The seventh switching device SW7 is coupled between an input of the comparator (not shown) of the SAR ADC 650 and the lower voltage rail DC and/or AC ground or common mode voltage. The filter control circuit 610 are coupled to switching devices SW1-SW7, configured to generate the control signals EN, EN_B, φ1-φ4, and φreset for the switching devices, respectively.

The SAR ADC 650 includes a sampling switching device SW8, a set of capacitors CDAC, and a switch unit 652. The sampling switching device SW8 coupled between the output of the switched capacitor filter 600 and the input of the SAR ADC comparator. The sampling switching device SW8 is responsive to the sampling clock signal φS of the SAR ADC 650. The sampling clock signal φS may be the same or based on the sampling clock signal f_{S}. The set of capacitors CDAC is coupled between the input of the SAR ADC comparator and the switch unit 652. The switch unit 652 is controlled by a SAR logic and calibration processor (not shown) to apply the appropriate potentials (e.g., ground, reference voltage, positive reference voltage, negative reference voltage, common mode voltage, etc.) to effectuate the analog-to-digital conversion of the baseband voltage signal V_{BB2} into a digital baseband signal D_{BB}.

FIG. 6B illustrates a timing diagram of an example operation of the switched capacitor FIR filter 600 in accordance with another aspect of the disclosure. The horizontal axis of the timing diagram represents time. The vertical axis, from top to bottom, represents the states of the SAR ADC sampling clock signal φS, the conversion signal φconv, the reset signal reset, the phase signal φ1, the phase signal φ2, the phase signal φ3, and the phase signal φ4. In this example, the switched capacitor FIR filter 600 is enabled (e.g., EN=1, EN_B=0).

The operation of the switched capacitor FIR filter 600 operates as follows: The description of the operation starts at time t₁. At time t₁, the first phase signal φ1 becomes a logic one (1) or high causing the third switching device SW3 to turn ON (e.g., at such time t₁, the switching devices SW4-SW7 are OFF). Thus, the first set of one or more capacitors C1 samples the input baseband signal V_{BB1} (e.g., producing charges across the capacitor C1 based on a first sample of V_{BB1}). At time t₂, the first phase signal φ1 becomes a logic zero (0) or low causing the third switching device SW3 to turn OFF. At time t₃, the third phase signal φ3 becomes a logic one (1) or high causing the fourth switching device SW4 to turn ON. Thus, the second set of one or more capacitors C2 samples the input baseband signal V_{BB1} (e.g., producing charges across the capacitor C2 based on a second sample of V_{BB1}).

At time t₄, the third phase signal φ3 becomes logic zero (0) or low causing the fourth switching device SW4 to turn OFF. Also, at time t₄, the fourth phase signal φ4 becomes a logic one (1) or high causing the fifth and sixth switching devices SW5 and SW6 to turn ON. At such time, charge sharing between the first set of one or more capacitors C1 and the second set of one or more capacitors C2 occur at the output of the switched capacitor filter 600 to perform the FIR filtering of the first received baseband signal V_{BB1}. Additionally, at time t₄, the sampling phase signal φS become a logic one (1) or high to cause the sampling switching device SW8 of the SAR ADC 650 to turns ON so that the SAR ADC 650 samples the filtered baseband signal V_{BB2} at the output by transferring the shared charges to the capacitors CDAC of the SAR ADC 650.

At time t₅, the fourth phase signal φ4 becomes a logic zero (0) or low causing the fifth and sixth switching devices SW5 and SW6 to turn OFF to isolate the SAR ADC 650 from the filter operation of the switched capacitor FIR filter 650 for the next filtering cycle. Also, at time t₅, the sampling phase signal φS become logic zero (0) or low to isolate the analog-to-digital operation of the SAR ADC 650 from the filtering operation of the switched capacitor FIR filter 650. During time interval t₅-t₆, the conversion phase signal φconv exhibits a set of N pulses (e.g., N=10 for an N-bit SAR ADC 650) to perform the successive approximation conversion of the filtered baseband signal V_{BB1} into the digital baseband signal D_{BB}. Then, at time t₇, the reset phase signal φreset becomes a logic one (1) or high to clear the voltage (e.g., set to OV, common mode voltage, AC ground) at the input of the SAR ADC comparator. Then, at time t₈, the reset phase signal preset becomes a logic zero (0) or low to free the input of the SAR ADC comparator to receive the next sample of the filtered baseband signal V_{BB2}.

The switched capacitor FIR filter 600 may have the following z-domain transfer function:

$$STF = \frac{{V}_{{BB}_{2}}}{{V}_{{BB}_{1}}} = \frac{{C}_{1} {z}^{- 3} + {C}_{2} {z}^{- 1}}{{C}_{1} + {C}_{2} + {C}_{DAC}} \qquad Eq . 1$$

And the DC gain associated with the switched capacitor FIR filter 600 may be represented as follows:

$$DC Gain = \frac{{C}_{1} + {C}_{2}}{{C}_{1} + {C}_{2} + {C}_{DAC}} \qquad Eq . 2$$

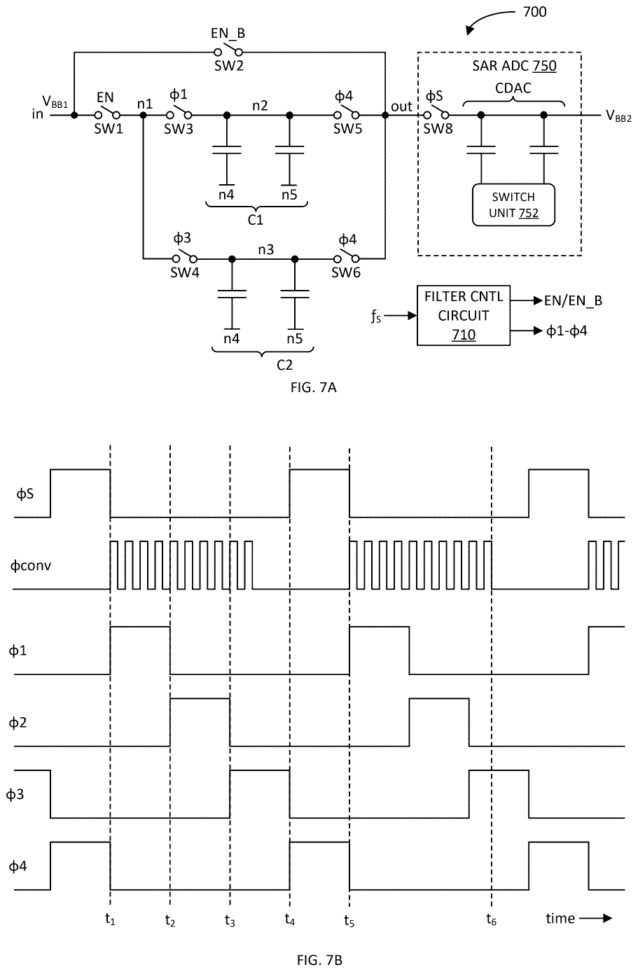

FIG. 7A illustrates a schematic diagram of another example switched capacitor infinite impulse response (IIR) filter 700 in accordance with another aspect of the disclosure. The switched capacitor IIR filter 700 is similar to the switched capacitor FIR filter 600 including the set of switching devices SW1-SW6, the first set of one or more capacitors C1, the second set of one or more capacitors C2, and a filter control circuit 710 in the same arrangement as the corresponding elements in switched capacitor FIR filter 600. The filter control circuit 710 is configured to generate the control signals EN, EN_B and φ1-φ4. The difference between the switched capacitor IIR filter 700 and the switched capacitor FIR filter 600 is that the filter 700 does not include the seventh switching device SW7 related to the resetting operation of the FIR filter 600; and thus, the filter control circuit 710 does not generate the corresponding control signal preset.

FIG. 7B illustrates a timing diagram of an example operation of the switched capacitor infinite impulse response (IIR) filter 700 in accordance with another aspect of the disclosure. The timing diagram is similar to the timing diagram of FIG. 6B. The timing operation of the switched capacitor IIR filter 700 is basically the same as the timing diagram related to the operation of the switched capacitor FIR filter 600 with the exception of the operation of the reset switching device as the reset switching device may not be included in the switched capacitor IIR filter 700.

The switched capacitor FIR filter 600 may have the following z-domain transfer function:

$$STF = \frac{{V}_{{BB}_{2}}}{{V}_{{BB}_{1}}} = \frac{{C}_{1} {z}^{- 3} + {C}_{2} {z}^{- 1}}{( {C}_{1} + {C}_{2} + {C}_{DAC} ) - {C}_{DAC} {Z}^{- 4}} \qquad Eq . 3$$

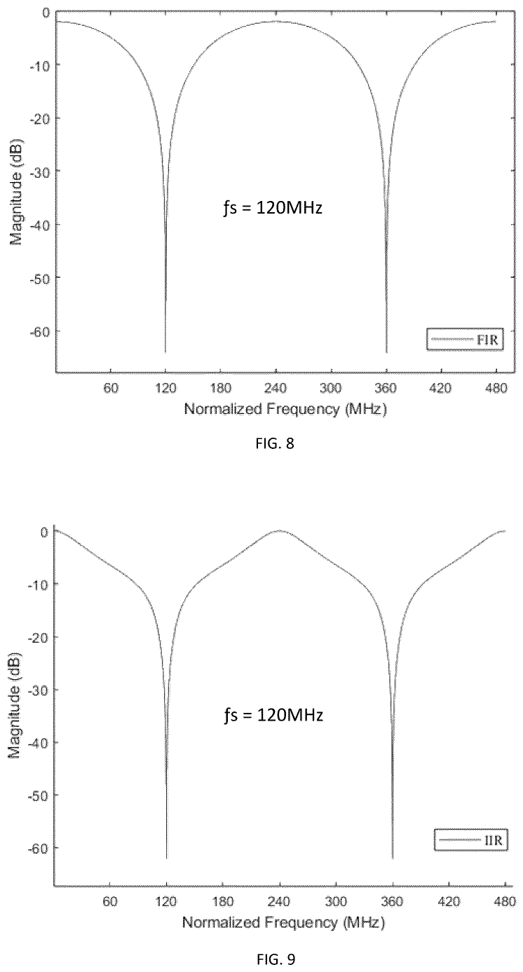

FIG. 8 illustrates a graph of an example transfer function of the switched capacitor finite impulse response (FIR) filter 600 in accordance with another aspect of the disclosure. The horizontal axis represents normalized frequency in MHz ranging from 0 Hz to 480 MHz. The vertical axis represents the magnitude of the transfer function in decibels (dBs) ranging from −80 dB to 20 dB.

If the capacitance of the first set of one or more capacitors C1 is set to substantially the same as the capacitance of the second set of one or more capacitors C2, the transfer function of the switched capacitor FIR filter 600 includes notches at the sampling frequency f_{S} below and above the center of the passband of the switched capacitor FIR filter 600. In this example, the sampling frequency f_{S} is at 120 MHz. Accordingly, the center frequency of the passband is at 240 MHz. The lower and upper notches are at 120 MHz and 360 MHz, respectively. Each of the notches provide more than 60 dB of attenuation to substantially reduce or effectively eliminate any anti-aliasing effects.

FIG. 9 illustrates a graph of an example transfer function of the switched capacitor infinite impulse response (IIR) filter 700 in accordance with another aspect of the disclosure. Similarly, the horizontal axis represents normalized frequency in MHz ranging from 0 Hz to 480 MHz. The vertical axis represents the magnitude of the transfer function in decibels (dBs) ranging from −80 dB to 20 dB.

If the capacitance of the first set of one or more capacitors C1 is set to substantially the same as the capacitance of the second set of one or more capacitors C2, the transfer function of the switched capacitor IIR filter 700 includes notches at the sampling frequency f_{S} below and above the center of the passband of the switched capacitor IIR filter 700. In this example, the sampling frequency f_{S} is at 120 MHz. Accordingly, the center frequency of the passband is at 240 MHz. The lower and upper notches are at 120 MHz and 360 MHz, respectively. Similarly, each of the notches provide more than 60 dB of attenuation to substantially reduce or effectively eliminate any anti-aliasing effects.

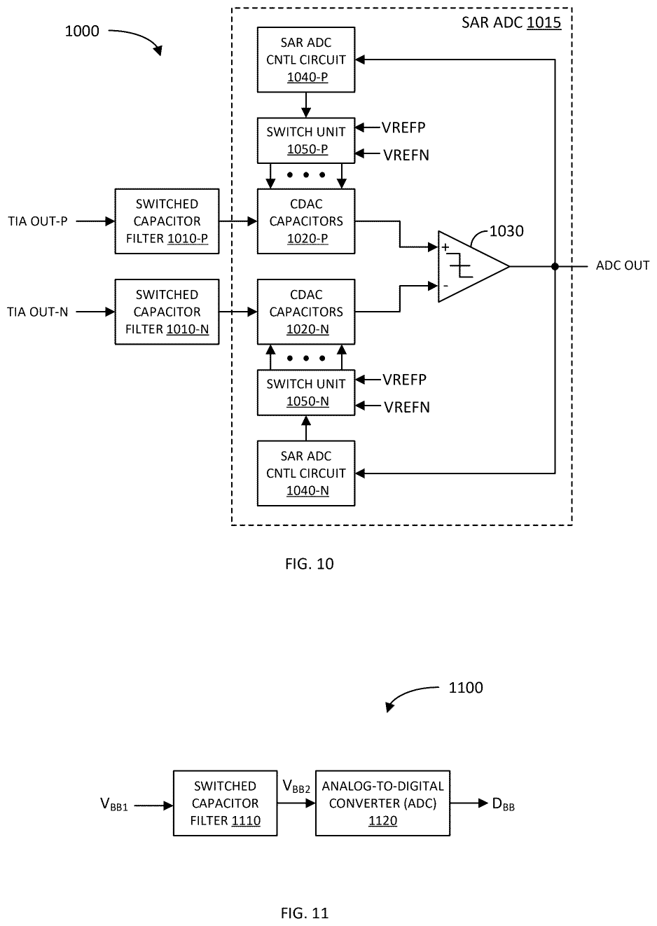

FIG. 10 illustrates a block diagram of another example baseband signal processing circuit 1000 in accordance with another aspect of the disclosure. The switched capacitor FIR and IIR filters 600 and 700 previously discussed has been shown to be implemented as single-ended signaling FIR and IIR filters. However, as also mentioned, the switched capacitor FIR and IIR filters 600 and 700 may be implemented as differential signaling FIR and IIR filters.

In this regard, the baseband signal processing circuit 1000 includes a positive-differential-side (p-side) switched capacitor filter 1010-P, a negative-differential-side (n-side) switched capacitor filter 1010-N, and a differential SAR ADC 1015. The differential SAR ADC 1015, in turn, includes a set of p-side CDAC capacitors 1020-P, a set of n-side CDAC capacitors 1020-N, a comparator 1030, a p-side SAR ADC control circuit 1040-P, an n-side SAR ADC control circuit 1040-N, a p-side switch unit 1050-P, and an n-side switch unit 1050-N.

The p-side switched capacitor filter 1010-P may be implemented per switched capacitor FIR filter 600 to effectuate an FIR transfer function per Eq. 1. Similarly, the n-side switched capacitor filter 1010-N may be implemented per switched capacitor FIR filter 600 to effectuate an FIR transfer function per Eq. 1. Alternatively, the p-side switched capacitor filter 1010-P may be implemented per switched capacitor IIR filter 700 to effectuate an IIR transfer function per Eq. 3. Similarly, the n-side switched capacitor filter 1010-N may be implemented per switched capacitor IIR filter 700 to effectuate an FIR transfer function per Eq. 3.

The p-side switched capacitor filter 1010-P includes an input coupled to a p-side output of a differential transimpedance amplifier (TIA), which may be implemented per TIA 410 or 510. The n-side switched capacitor filter 1010-N includes an input coupled to an n-side output of the differential amplifier TIA, which may be implemented per TIA 410 or 510.

The p-side switched capacitor filter 1010-P includes an output coupled to the set of p-side CDAC capacitors 1020-P of the SAR ADC 1015. The n-side switched capacitor filter 1010-N includes an output coupled to the set of n-side CDAC capacitors 1020-N of the SAR ADC 1015. The set of p-side CDAC capacitors 1020-P may be implemented per any of the set of CDAC capacitors of the SAR ADC 530, 650, and 750 previously discussed. Similarly, the set of n-side CDAC capacitors 1020-N may be implemented per any of the set of CDAC capacitors of the SAR ADC 530, 650, and 750 previously discussed.

The comparator 1030 includes a positive (+) input coupled to the set of p-side CDAC capacitors 1020-P. The comparator 1030 includes a negative (+) input coupled to the set of n-side CDAC capacitors 1020-N. The comparator 1030 includes an output coupled to an input of the p-side SAR ADC control circuit 1040-P. The output of the comparator 1030 is also coupled to an input of the n-side SAR ADC control circuit 1040-N. The p-side SAR ADC control circuit 1040-P includes an output coupled to an input of the p-side switch unit 1050-P. The n-side SAR ADC control circuit 1040-N includes an output coupled to an input of the n-side switch unit 1050-N.

The p-side switch unit 1050-P includes a set of outputs coupled to the set of p-side CDAC capacitors, respectively. The n-side switch unit 1050-N includes a set of outputs coupled to the set of n-side CDAC capacitors, respectively. Both the switch units 1050-N and 1050-P include respective inputs configured to receive a p-side reference voltage VREFP and an n-side reference voltage VREFN.

FIG. 11 illustrates a block diagram of another example apparatus 1100 (e.g., at least a portion of a receiver) in accordance with another aspect of the disclosure. The apparatus 1100 includes a switched capacitor filter 1110, and an analog-to-digital converter (ADC) 1120 including an input coupled to the switched capacitor filter 1110.

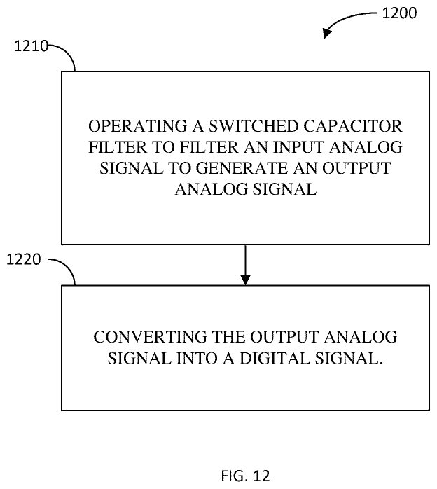

FIG. 12 illustrates a flow diagram of an example method 1200 of filtering a baseband signal in accordance with another aspect of the disclosure. The method 1200 includes operating a switched capacitor filter to filter an input analog signal to generate an output analog signal (block 1210). Examples of means for operating a switched capacitor filter to filter an input analog signal to generate an output analog signal include any of the switched capacitor filters described herein. The method 1200 further includes converting the output analog signal into a digital analog signal (block 1220). Examples of means for converting the output analog signal into a digital signal include any of the SAR ADCs described herein.

The following provides an overview of aspects of the present disclosure:

Aspect 1: An apparatus, comprising: a switched capacitor filter; and an analog-to-digital converter (ADC) including an input coupled to the switched capacitor filter.

Aspect 2: The apparatus of aspect 1, wherein the switched capacitor filter comprises a finite impulse response (FIR) switched capacitor filter.

Aspect 3: The apparatus of aspect 1, wherein the switched capacitor comprises an infinite impulse response (IIR) switched capacitor filter.

Aspect 4: The apparatus of any one of aspects 1-3, wherein the ADC comprises a successive approximation register (SAR) ADC.

Aspect 5: The apparatus of any one of aspects 1-4, a first switching device coupled between an input and a first node; a first set of one or more capacitors coupled between the first node and a set of one or more nodes; a second switching device coupled between the input and a second node; a second set of one or more capacitors coupled between the second node and the set of one or more nodes; a third switching device coupled between the first node and an output; and a fourth switching device coupled between the third node and the output.

Aspect 6: The apparatus of aspect 5, wherein the set of one or more nodes includes a lower voltage rail.

Aspect 7: The apparatus of aspect 5 or 6, wherein the set of one or more nodes includes ground.

Aspect 8: The apparatus of any one of aspects 5-7, wherein the set of one or more nodes is coupled to a source of a common mode voltage.

Aspect 9: The apparatus of any one of aspects 5-7, wherein the set of one or more nodes includes a first source of a positive reference voltage and a second source of a negative reference voltage.

Aspect 10: The apparatus of any one of aspects 5-9, further comprising a control circuit coupled to the first switching device, the second switching device, the third switching device, and the fourth switching device.

Aspect 11: The apparatus of aspect 10, wherein the ADC comprises a successive approximation register (SAR) ADC, comprising: a comparator including an input; a fifth switching device coupled between the output of the switched capacitor filter and the input of the comparator; a switch unit; and a set of capacitors coupled between the input of the comparator and the switch unit.

Aspect 12: The apparatus of aspect 11, wherein the switched capacitor filter comprises a fifth switching device coupled between the input of the comparator and a lower voltage rail, ground, a source of a reference voltage, or a source of a common mode voltage.

Aspect 13: The apparatus of aspect 12, wherein the control circuit is coupled to the fifth switching device.

Aspect 14: The apparatus of any one of aspects 5-13, wherein the switched capacitor filter further comprises: a fifth switching device coupled between the input and the first switching device; and a sixth switching device coupled between the input and the output.

Aspect 15: The apparatus of aspect 14, further comprising a control circuit coupled to the fifth switching device and the sixth switching device.

Aspect 16: A method, comprising: operating a switched capacitor filter to filter an input analog signal to generate an output analog signal; and converting the output analog signal into a digital signal.

Aspect 17: The method of aspect 16, wherein operating the switched capacitor filter, comprises: providing the input analog signal to a second set of one or more capacitors during a second phase of the clock signal; and providing the input analog signal to a second set of one or more capacitors during a second phase of the clock signal; and effectuating sharing of charges formed on the first set of one or more capacitors and the second set of one or more capacitors during the first and second phases of the clock signal at a node to form the output analog signal during a third phase of the clock signal.

Aspect 18: The method of aspect 17, wherein converting the output analog signal into the digital signal comprises sampling the output analog signal during a fourth phase of the clock signal.

Aspect 19: The method of aspect 18, further comprising clearing the output analog signal during a fifth phase of the clock signal.

Aspect 20: The method of aspect 18, wherein sampling the output analog signal comprises combining the sampled output analog signal with one or more previous samples of the output analog signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a switched capacitor filter; and
an analog-to-digital converter (ADC) including an input coupled to the switched capacitor filter.

2. The apparatus of claim 1, wherein the switched capacitor filter comprises a finite impulse response (FIR) switched capacitor filter.

3. The apparatus of claim 1, wherein the switched capacitor filter comprises an infinite impulse response (IIR) switched capacitor filter.

4. The apparatus of claim 1, wherein the ADC comprises a successive approximation register (SAR) ADC.

5. The apparatus of claim 1, wherein the switched capacitor filter comprises:
a first switching device coupled between an input and a first node;
a first set of one or more capacitors coupled between the first node and a set of one or more nodes;
a second switching device coupled between the input and a second node;
a second set of one or more capacitors coupled between the second node and the set of one or more nodes;
a third switching device coupled between the first node and an output; and
a fourth switching device coupled between the third node and the output.

6. The apparatus of claim 5, wherein the set of one or more nodes includes a lower voltage rail.

7. The apparatus of claim 5, wherein the set of one or more nodes includes ground.

8. The apparatus of claim 5, wherein the set of one or more nodes is coupled to a source of a common mode voltage.

9. The apparatus of claim 5, wherein the set of one or more nodes includes a first source of a positive reference voltage and a second source of a negative reference voltage.

10. The apparatus of claim 5, further comprising a control circuit coupled to the first switching device, the second switching device, the third switching device, and the fourth switching device.

11. The apparatus of claim 10, wherein the ADC comprises a successive approximation register (SAR) ADC, comprising:
a comparator including an input;
a fifth switching device coupled between the output of the switched capacitor filter and the input of the comparator;
a switch unit; and
a set of capacitors coupled between the input of the comparator and the switch unit.

12. The apparatus of claim 11, wherein the switched capacitor filter comprises a fifth switching device coupled between the input of the comparator and a lower voltage rail, ground, a source of a reference voltage, or a source of a common mode voltage.

13. The apparatus of claim 12, wherein the control circuit is coupled to the fifth switching device.

14. The apparatus of claim 5, wherein the switched capacitor filter further comprises:
a fifth switching device coupled between the input and the first switching device; and
a sixth switching device coupled between the input and the output.

15. The apparatus of claim 14, further comprising a control circuit coupled to the fifth switching device and the sixth switching device.

16. A method, comprising:
operating a switched capacitor filter to filter an input analog signal to generate an output analog signal; and
converting the output analog signal into a digital signal.

17. The method of claim 16, wherein operating the switched capacitor filter, comprises:
providing the input analog signal to a first set of one or more capacitors during a first phase of a clock signal;
providing the input analog signal to a second set of one or more capacitors during a second phase of the clock signal; and
effectuating sharing of charges formed on the first set of one or more capacitors and the second set of one or more capacitors during the first and second phases of the clock signal at a node to form the output analog signal during a third phase of the clock signal.

18. The method of claim 17, wherein converting the output analog signal into the digital signal comprises sampling the output analog signal during a fourth phase of the clock signal.

19. The method of claim 18, further comprising clearing the output analog signal during a fifth phase of the clock signal.

20. The method of claim 18, wherein sampling the output analog signal comprises combining the sampled output analog signal with one or more previous samples of the output analog signal.
